(19) United States
(12) Patent Application Publication
(10) Pub. No.: US 2018/0100088 A1
(43) Pub. Date: Apr. 12, 2018

(54) COVER WINDOW AND DISPLAY DEVICE INCLUDING THE SAME

(71) Applicant: Samsung Display Co., Ltd., Yongin-si (KR)

(72) Inventors: Hung Kun AHN, Seongnam-si (KR); Dong Eun LEE, Asan-si (KR); Ki Tae KIM, Seongnam-si (KR); Sang Gu KIM, Seoul (KR); Hyun-Woo CHOI, Hwaseong-si (KR)

(21) Appl. No.: 15/782,574

(22) Filed: Oct. 12, 2017

(30) Foreign Application Priority Data
Oct. 12, 2016 (KR) 10-2016-0132289

(51) Int. Cl. C09J 7/02; G06F 1/16; C09J 129/02; H01L 51/52; H01L 27/32; C08J 7/04

(52) U.S. Cl. CPC C09J 7/0275; G06F 1/1637; C09J 7/0207; C08J 7/045; H01L 51/52; H01L 27/32; C09J 129/02

(57) ABSTRACT

A cover window according to an exemplary embodiment includes: a polymer resin layer; and a film positioned on one surface of the polymer resin layer, wherein the polymer resin layer includes a matrix and particles having a core/shell structure dispersed in the matrix, a core of the particles includes polymethyl methacrylate, and a shell of the particles includes a copolymer of butyl acrylate and styrene.

### CROSS-REFERENCE TO RELATED APPLICATION

This application claims priority to and the benefit of Korean Patent Application No. 10-2016-0132289, filed in the Korean Intellectual Property Office on Oct. 12, 2016, the entire content of which is incorporated herein by reference.

### BACKGROUND

### 1. Field

The present disclosure relates to a cover window and a display device including the same.

### 2. Description of the Related Art

Display devices that are currently known include liquid crystal displays (LCD), plasma display devices (e.g., plasma display panels: PDP), emissive display devices (e.g., light emitting displays: OLED), electric field display devices (e.g., field emission displays: FED), electrophoretic display devices (e.g., electrophoretic display devices), and the like. A display device includes a display module displaying an image and a cover window protecting the display module.

Glass may be utilized as the cover window. However, the glass may be easily broken by an external impact. Therefore damage may be easily generated when the glass is applied to a portable apparatus, such as a mobile device. Accordingly, a cover window made of a plastic material instead of a glass has been recently researched.

On the other hand, when the portable apparatus includes a display device with a touch function, a finger and/or a sharp tool such as a pen is frequently in contact with one side (e.g., one surface) of the cover window. Here, a scratch may be easily generated on the surface of the cover window made of the plastic material. To reduce or prevent the scratch from being easily generated on the surface of the cover window made of the plastic material, a coating process to produce a hard coat with a high hardness, e.g., with a pencil hardness of 7H, is executed. However, the cover window may be partially broken when the portable apparatus having the plastic cover window coated with a brittle hard coat surface is dropped due to the high hardness of the hard coat.

The above information disclosed in this Background section is only for enhancement of understanding of the background of the invention and therefore it may contain information that does not form prior art.

### SUMMARY

Aspects according to one or more embodiments of the present disclosure are directed toward a cover window with improved impact resistance and hardness, and a display device including the same.

Additional aspects will be set forth in part in the description which follows and, in part, will be apparent from the description, or may be learned by practice of the presented embodiments.

A cover window according to an exemplary embodiment includes: a polymer resin layer; and a film on one surface of the polymer resin layer, wherein the polymer resin layer includes a matrix and particles having a core/shell structure in the matrix, a core of the particles having the core/shell structure includes polymethyl methacrylate, and a shell of the particles having the core/shell structure includes a copolymer of butyl acrylate and styrene.

The matrix may include polymethyl methacrylate.

Polymethyl methacrylate grafted to an outermost portion of the particles may be further included.

A content of the particles may be in a range of 10 wt % to 20 wt % based on a total weight of the polymer resin layer.

A thickness of the polymer resin layer may be in a range of 600 μm to 1000 μm.

The film may include at least one material selected from the group consisting of polyethylene terephthalate (PET), polyethylene naphthalate (PEN), a cycloolefin polymer (COP), and polycarbonate (PC).

The thickness of the film may be in a range of 100 μm to 200 μm.

An adhesive layer between the film and the polymer resin layer may be further included.

The adhesive layer may include an optically clear adhesive, and an adherence thereof may be 30 N/inch or greater.

An entire thickness of the cover window may be 1200 μm or less.

A pencil hardness of the cover window may be 4H or greater.

A content of the particles may be in a range of 10 wt % to 16 wt % based on a total weight of the polymer resin layer.

A pencil hardness of the cover window may be 7H or greater.

A hard coating layer on the other surface of the polymer resin layer may be further included.

A light blocking layer on one surface of the film may be further included.

A display device according to an exemplary embodiment includes: a display panel; and a cover window on one surface of the display panel, wherein the cover window includes a polymer resin layer and a film on one surface of the polymer resin layer, the polymer resin layer includes a matrix and particles having a core/shell structure dispersed in the matrix, a core of the particles having the core/shell structure includes polymethyl methacrylate, and a shell of the particles having the core/shell structure includes a copolymer of butyl acrylate and styrene.

The matrix may include polymethyl methacrylate.

Polymethyl methacrylate grafted to an outermost portion of the particle may be further included.

A content of the particles may be in a range of 10 wt % to 20 wt % based on a total weight of the polymer resin layer.

A hard coating layer on the polymer resin layer, and a light blocking layer between the film and the display panel, may be further included.

According to exemplary embodiments, both the impact resistance and the hardness of the cover window may be improved.

### BRIEF DESCRIPTION OF THE DRAWINGS

Aspects of some example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

FIG. 1 is a cross-sectional view of a cover window according to an exemplary embodiment.

FIG. 2A is a cross-sectional view of a core/shell particle according to an example embodiment.

FIG. 2B is an actual image of a core/shell particle according to an exemplary embodiment.

FIG. 3 is an image where core/shell particles are positioned in a PMMA matrix according to an exemplary embodiment.

FIGS. 4A to 4C are schematic illustrations showing a principle (e.g., mechanism) of impact absorption by a cover window including core/shell particles.

FIG. 5 is a cross-sectional view showing a cover window according to another exemplary embodiment.

FIG. 6 is a cross-sectional view of a display device including a cover window according to an exemplary embodiment.

### DETAILED DESCRIPTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present disclosure. Accordingly, the drawings and description are to be regarded as illustrative in nature and not restrictive.

In order to clearly explain embodiments of the present invention, portions that are not directly related to embodiments of the present invention are omitted, and the same reference numerals are used to refer to the same or similar constituent elements through the entire specification.

In addition, the size and thickness of each configuration shown in the drawings may be arbitrarily shown for better understanding and ease of description, but embodiments of the present invention are not limited thereto. In the drawings, the thickness and area of layers, films, panels, regions, etc., may be exaggerated for clarity, and for better understanding and ease of description.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, spatially relative terms, such as “on,” “below,” “beneath,” “lower,” “above,” “upper,” and the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings.

In addition, unless explicitly described to the contrary, the word “comprise” and variations such as “comprises” or “comprising” will be understood to imply the inclusion of stated elements but not the exclusion of any other elements.

Further, in the specification, the phrase “in a plan view” refers to when an object portion is viewed from a position above it, and the phrase “in a cross-sectional view” refers to when a cross-section taken by vertically cutting an object portion is viewed from the side.

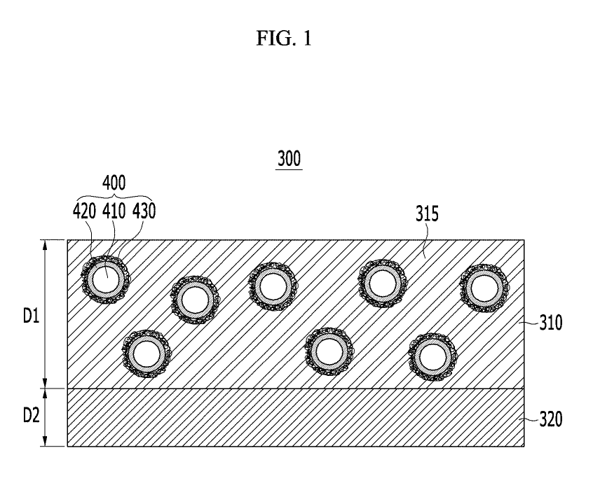

Next, a cover window according to an exemplary embodiment will be described with reference to accompanying drawings. FIG. 1 is a cross-sectional view of a cover window according to an exemplary embodiment.

Referring to FIG. 1, the cover window 300 according to the present exemplary embodiment includes a polymer resin layer 310 and a film 320 positioned at one surface of the polymer resin layer.

The polymer resin layer 310 includes a matrix 315 and particles 400 of a core/shell structure dispersed in the matrix. A core 410 of the particles 400 includes polymethyl methacrylate (PMMA), and a shell 420 of the particles 400 includes a copolymer of butyl acrylate and styrene. The particles 400 may further include polymethyl methacrylate grafted to an outermost portion 430 (e.g., an outermost portion 430 of the shell 420).

The matrix 315 of the polymer resin layer 310 may include a transparent plastic material (i.e., a transparent polymeric material) with high hardness. In more detail, the matrix 315 may include polymethyl methacrylate (PMMA).

The cover window 300 according to the present exemplary embodiment includes the polymer resin layer 310, which includes the particles 400 with the core/shell structure. In one embodiment, the particle 400 is a rubber particle with a core 410 including the PMMA, a shell 420 including a copolymer of butyl acrylate and styrene enclosing the core, and PMMA grafted to the outermost portion of the particle 400. Here, the PMMA included in the core 410 may have higher elasticity than the PMMA included in the matrix. Accordingly, when an impact is applied to the cover window, the PMMA core having the higher elasticity absorbs the impact. Further, because the butyl acrylate of the shell 420 and the copolymer of butyl acrylate and styrene have high elasticity, when the impact energy applied from the outside is absorbed, the transmission of the impact energy to the polymethyl methacrylate (PMMA) matrix 315 is reduced or prevented, thereby increasing the impact resistance of the cover window 300. The PMMA grafted to the outermost portion of the particle 400 improves a physicochemical bond characteristic of an interface between the core/shell particle 400 and the matrix 315. That is, because the same material as the PMMA of the matrix 315 is also positioned at the surface of the core/shell particle 400, a bonding force of the particle 400 and the matrix 315 may be improved.

In an exemplary embodiment, a size of the particle 400 may be in a range of 0.2 μm to 0.5 μm. The size of the particle 400 may be suitably changed depending on the material of the matrix 315.

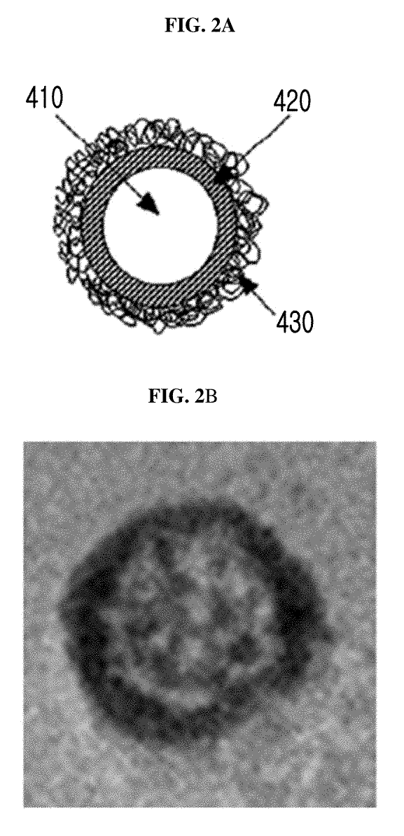

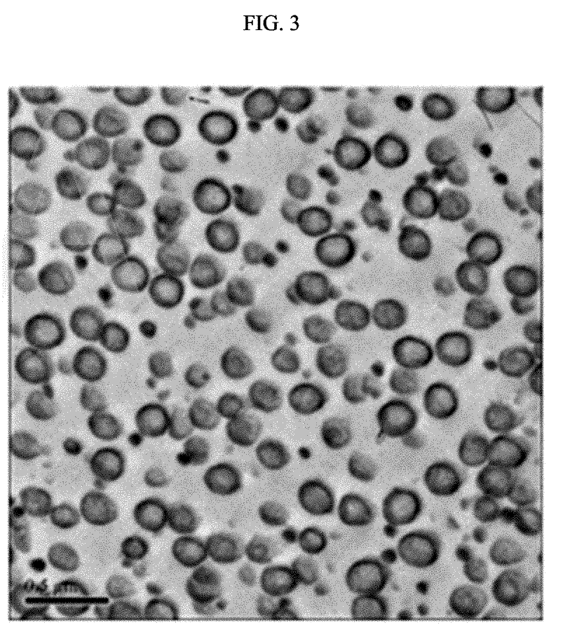

FIG. 2A is a cross-sectional view and FIG. 2B is an actual image of a core/shell particle according to an exemplary embodiment (e.g., taken by a transmission scanning microscope). FIG. 3 is an image showing core/shell particles positioned in a PMMA matrix according to an exemplary embodiment.

When the impact is applied to the cover window, the cover window having the above-described structure reduces or prevents the damage of the cover window, as the particles 400 of the core/shell structure absorbs the impact.

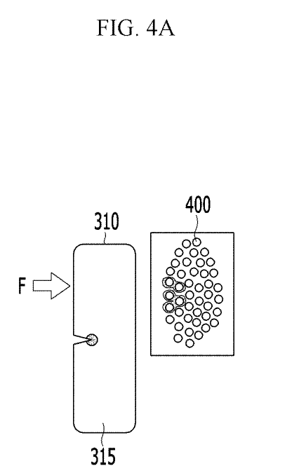

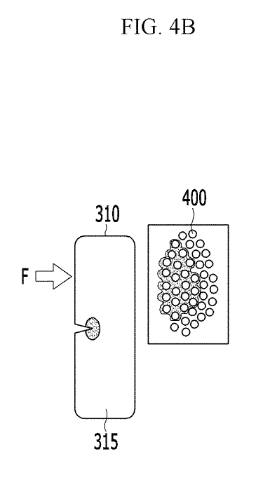

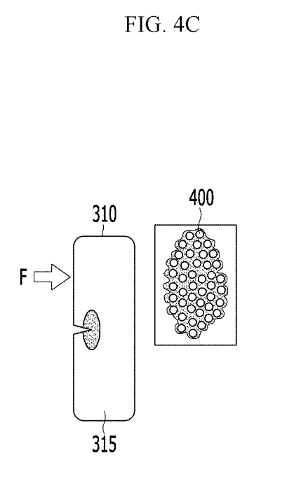

FIGS. 4A to 4C are schematic illustrations showing a principle (e.g., mechanism) of impact absorption by a cover window including core/shell particles. The size of the impact and an absorption degree of the impact (e.g., the amount of core/shell particles involved in the absorption of the impact) are respectively indicated by a shaded region in the cross sectional view of the polymer resin layer (left image) and the magnified cross sectional view of the polymer resin layer around the impact area (right image) in FIGS. 4A to 4C. As shown in FIGS. 4A to 4C, when the impact F is applied from the outside, the particles 400 included inside the polymer resin layer 310 absorb the impact. When the impact is small, the impact is only absorbed by some (e.g., a few) particles (FIG. 4A). As the size of the impact becomes larger, more particles are involved. When the impact is large, the impact absorption occurs on substantially all particles (FIG. 4C). The impact absorption by the particles of the core/shell structure may be achieved (e.g., obtained) as the particle itself has the elasticity. Also, the impact may be absorbed while the particles move inside the matrix 315 (e.g., the movement of the particles inside the matrix 315 contributes to the absorption of the impact).

Accordingly, as will be described later, the cover window according to embodiments of the present disclosure may obtain good (e.g., excellent) performance in a ball drop test. That is, the impact resistance of the cover window is excellent. During the ball drop test, a metal ball having a set or predetermined weight is dropped on the cover window from various heights (e.g., with an increment on height of 30 cm or more) and the maximum height at which the cover window is not broken is recorded (e.g., measured).

A content of the particles 400 in the polymer resin layer 310 may be in a range of 10 wt % to 20 wt % with respect to (e.g., based on the total weight of) the polymer resin layer 310. As the content of the particles 400 increases, the value of the ball drop test is improved and the impact resistance increases. However, the hardness of the cover window may decrease as the content of the particles 400 increases.

For example, when the content of the particles 400 is less than 10 wt %, the ball drop test result may be not more than 30 cm. Also, when the content of the particles 400 is over 20 wt %, the elasticity of the polymer resin layer 310 greatly increases, so the pencil hardness of 4H or more may not be obtained even if the thickness of the hard coating layer increases. Accordingly, in one embodiment, the content of the particle 400 is in the range of 10 wt % to 20 wt %.

In an exemplary embodiment, when the content of the particles is in the range of 10 wt % to 16 wt %, the pencil hardness of the cover window may be 7H or greater.

The thickness D1 of the polymer resin layer 310 may be in a range of 600 μm to 1000 μm. For example, the thickness D1 may be 600 μm to 800 μm. However, the thickness of the polymer resin layer 310 is not limited thereto. Further, when the polymer resin layer 310 becomes too thin (e.g., less than 600 μm), the impact resistance of the cover window may be weak, whereas the entire thickness of the cover window may become too thick when the polymer resin layer 310 is excessively thick (e.g., thicker than 1000 μm).

The film 320 is positioned on one surface of the polymer resin layer 310. Although not shown in FIG. 1, an adhesive layer is positioned between the film 320 and the polymer resin layer 310 such that the film 320 and the polymer resin layer 310 may be strongly adhered (e.g., bonded). For example, the adhesive layer may be a transparent adhesive layer including an optically clear adhesive (OCA), and adherence (e.g., adhesion strength) thereof may be 30 N/inch or more.

The film 320 may include at least one material selected from polyethylene terephthalate (PET), polyethylene naphthalate (PEN), a cycloolefin polymer (COP), and polycarbonate (PC).

With the adhesive layer and the film 320 placed on one surface of the polymer resin layer 310, even when the cover window is broken, the broken pieces may be prevented or substantially prevented from scattering and the impact applied to the polymer resin layer 310 may be absorbed (e.g., the impact may be further absorbed by the adhesive layer and the film 320).

For this purpose, the thickness D2 of the film 320 may be in the range of 100 μm to 200 μm. When the thickness of the film is less than 100 μm, the impact may not be absorbed to a sufficient degree. Also, when the thickness of the film is over 200 μm, the entire thickness of the cover window may become too thick.

As described above, when the rubber particles of the core/shell structure are included inside the polymer resin layer 310 and the thickness of the film 320 is formed at 100 μm to 200 μm, both the impact resistance and the pencil hardness of the cover window may be improved.

When the polymer resin layer 310 includes a simple rubber material such as butadiene (instead of the rubber particles with the core/shell structure), the butadiene is randomly distributed inside the polymer resin layer 310 to improve the impact resistance. However, butadiene may change color when exposed to light in the process of utilizing the cover window. That is, the photo-sensitive portions (e.g., photoreactors) of the butadiene may react to bond to each other, and the transparent cover window may turn yellow. However, the cover window according to the present exemplary embodiment includes the particles of the core/shell structure (rather than the simple rubber material) to provide weathering resistance and to reduce or prevent such a phenomenon (e.g., yellowing of the cover window).

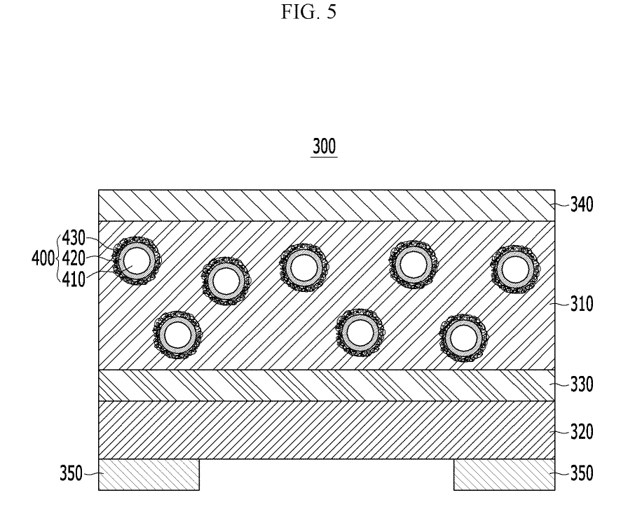

FIG. 1 shows a cover window in a simplified form according to an embodiment of the present disclosure, and the cover window according to another exemplary embodiment may have a structure as shown in FIG. 5. FIG. 5 is a cross-sectional view showing a cover window according to another exemplary embodiment.

Referring to FIG. 5, the cover window according to the present exemplary embodiment includes the polymer resin layer 310, a hard coating layer 340, an adhesive layer 330, the film 320, and a light blocking layer 350.

The hard coating layer 340 is disposed on one surface of the polymer resin layer 310, and the film 320 is adhered to the other (i.e., the opposite) surface of the polymer resin layer by the adhesive layer 330. The light blocking layer 350 is positioned on the other surface of the film 320 (i.e., on the surface facing away from the surface on the adhesive layer 330). The light blocking layer 350 may be printed on the film 320 or may be formed by a separate process.

The description of the polymer resin layer 310 and the film 320 is substantially the same as that described in reference to FIG. 1. The detailed description of the same constituent elements is not repeated again. Here, the polymer resin layer 310 includes the particles 400 having the core/shell structure, and the film 320 has the thickness of 100 μm to 200 μm. In the particles 400, the core 410 including the PMMA is enclosed by the copolymer shell 420 of butyl acrylate and styrene, and the PMAA is grafted to the outermost portion 430 of the shell 420.

The hard coating layer 340 is positioned on the surface of the cover window, thereby further improving the surface hardness. The hard coating layer 340 may include at least one material selected from an organic material, an inorganic material, and an organic/inorganic complex (e.g., hybrid or mixed) compound. Here, the organic material may include an acryl-based compound, an epoxy-based compound, or combinations thereof; the inorganic material may include silica, alumina, or combinations thereof; and the organic/inorganic complex compound may include polysilsesquioxane. For example, the hard coating layer 340 may be manufactured by immersing the polymer resin layer 310 in a solvent including an acryl-based curable resin and a nanosilica, removing the polymer resin layer 310 from the solvent to have a set or predetermined coating thickness, and then executing drying and UV irradiating (e.g., UV curing).

The hard coating layer 340 may be formed of a single layer or multiple layers. The thickness of the hard coating layer 340 may be in the range of 10 μm to 30 μm.

Although not shown in FIG. 5, a fingerprint prevention layer may be further included on one surface of the hard coating layer 340. The fingerprint prevention layer is formed with a thickness of less than 50 nm, solving the problem of fingerprints on the cover window surface.

The adhesive layer 330 as a layer positioned between the polymer resin layer 310 and the film 320 to bond them together may be formed from a transparent polymer resin. That is, the adhesive layer 330 may be a transparent adhesive layer. For example, the transparent adhesive layer may be an optically clear adhesive (OCA), a super view resin (SVR), a pressure sensitive adhesive (PSA), an optically clear resin (OCR), or combinations thereof, but the adhesive layer is not limited thereto. As an exemplary embodiment, the adhesive layer 330 may include an acryl-based binder. The thickness of the adhesive layer 330 may be in the range of 10 μm to 50 μm. For example, the adhesive layer 330 may be the transparent adhesive layer including the OCA, and the adherence (e.g., adhesion strength) may be 30 N/inch or more.

The light blocking layer 350 is positioned on one surface of the film 320 and includes a material capable of blocking light. The light blocking layer 350 is positioned along the edge of the film 320 to correspond to a bezel region when the cover window is applied to the mobile apparatus (such as the display device). However, the light blocking layer 350 may be omitted (i.e., may not be included).

Here, when the rubber particles with the core/shell structure are included in the polymer resin layer 310, the thickness of the adhesive layer 330 is formed at a range of 10 μm to 50 μm, and the thickness of the film 320 is formed at a range of 100 μm to 200 μm, both the impact resistance and the pencil hardness of the cover window may be improved.

In an exemplary embodiment, the entire thickness of the cover window may be less than 1200 μm. Accordingly, the cover window may be easily applied to various apparatuses, and even after the cover window is applied, the thickness of the apparatus may not significantly increase.

Next, the hardness and impact resistance strength of the cover window according to one or more embodiments of the present disclosure will be described in more detail based on experimental examples. Table 1 shows the impact resistance strength, the pencil hardness, and the weathering resistance of various samples prepared by differentiating (e.g., varying) the content of the core/shell particles, the thickness of the polymer resin layer, and the thickness of the film.

TABLE 1

| | | | Th | Emb. | Emb. | Emb. | Emb. | Emb. | Emb. | Emb. | Com. | Com. | Com. |
|---|---|---|---|---|---|---|---|---|---|---|---|---|---|
| | | | (μm) | 1 | 2 | 3 | 4 | 5 | 6 | 7 | 1 | 2 | 3 |
| Hard coating layer | | Organic/ | 25 | ○ | ○ | ○ | ○ | ○ | ○ | ○ | ○ | ○ | ○ |
| | | inorganic | | | | | | | | | | | |
| | | hybrid | | | | | | | | | | | |
| | | solution | | | | | | | | | | | |
| Polymer | Rubber | 10% | 600 | ○ | | | | | | | | | |
| resin | particle | | | | | | | | | | | | |
| layer | content of | | | | | | | | | | | | |
| (PMMA) | core/shell | | | | | | | | | | | | |
| | structure | | | | | | | | | | | | |
| | | 15% | 600 | | ○ | | | | | | | | |
| | | 20% | 600 | | | ○ | | | | | | | |
| | | 15% | 700 | | | | ○ | | | | | | |
| | | 15% | 800 | | | | | ○ | ○ | ○ | ○ | | |
| | Butadiene | 15% | 800 | | | | | | | | | ○ | |
| | rubber | | | | | | | | | | | | |
| | content | | | | | | | | | | | | |
| | Content X | 0% | 800 | | | | | | | | | | ○ |
| Adhesive layer/film | | OCA/PET | 25/100 | ○ | ○ | ○ | ○ | ○ | | | | | |
| | | OCA/PET | 25/125 | | | | | | ○ | | | | |
| | | OCA/PET | 25/188 | | | | | | | ○ | | | |

| | | | | | | | | | | |
|---|---|---|---|---|---|---|---|---|---|---|
| Entire thickness (μm) | 750 | 750 | 750 | 850 | 950 | 975 | 1038 | 825 | 825 | 825 |
| Pencil hardness | 7 H | 7 H | 4 H | 7 H | 7 H | 7 H | 7 H | 7 H | 7 H | 7 H |
| Ball drop (@130 g) (cm) | 30 | 60 | 90 | 90 | 120 | 130 | 140 | 60 | 70 | 5 |
| Weathering resistance (Yellow Index) | 2.0 | 2.0 | 2.0 | 2.2 | 2.4 | 2.5 | 2.6 | 2.3 | 6.7 | 1.9 |

Th—thickness;
Emb—Exemplary Embodiment;
Com—Comparative Example

The table records a limit (e.g., maximum) height at which no whitening or crack occurred in the cover window when the 130 g metal ball is dropped on the cover window from different heights in the ball drop test. This is an experiment to measure the impact resistance of the cover window, and the higher the height, the higher the impact resistance.

Also, the weathering resistance test measures the yellow index of the cover window after irradiating the sample with UV at 15 W for 72 hours. Since the cover window is transparent, an increase in the yellow index indicates that the polymer material inside the PMMA is reacted or decomposed by the UV, and that the cover window has a shorter lifetime. That is, as the value of the yellow index increases, it indicates that the cover window may turn yellow more rapidly in natural light due to the degradation (e.g., denaturation) of the polymer material, and the lifetime of the cover window may be shorter.

Referring to Table 1, it may be confirmed that the impact resistance is excellent in Exemplary Embodiments 1 to 7 in which the core/shell particles are included in the PMMA polymer resin layer compared with Comparative Example 3 without the core/shell particles. Here, the result of the ball drop test of Comparative Example 3 without the particles is 5 cm, while the result is excellent at 30 cm to 140 cm in the case of the exemplary Embodiments.

Also, for Exemplary Embodiment 7 including the PET film, the result of the ball drop test is more than two times that of Comparative Example 1, for which the other conditions are all substantially the same as Exemplary Embodiment 7 but without the PET film.

Also, when comparing Exemplary Embodiments 5 to 7 with different PET film thicknesses, it may be confirmed that the result of the ball drop test gets better as the thickness of the PET film becomes thicker. That is, it may be confirmed that the impact resistance of the cover window is improved as the thickness of the PET film is thicker.

Also, when comparing Exemplary Embodiments 1 to 3 with different content of the core/shell particles, it may be confirmed that the impact resistance may be improved as the content of the particles increases. However, surface hardness decreases as the content of the particles increases, and the hardness of Exemplary Embodiment 3 in which the content of the particles is 20 wt % appears to be the lowest at 4H. Accordingly, it may be confirmed that the content of the particles of over 20 wt % is not desirable.

Also, when comparing Exemplary Embodiment 7 including the core/shell particles with Comparative Example 2 including the butadiene rubber (instead of the core/shell particles) but with the same content as the core/shell particles in Exemplary Embodiment 7, it is confirmed that Comparative Example 2 has a weathering resistance evaluation result of 6.7, which is more than two times of the 2.6 of Exemplary Embodiment 7. Here, for Comparative Example 2, simply including the butadiene rubber inside the PMMA, the hardness or the impact resistance is satisfactory (e.g., more than a set or predetermined value), but the weathering resistance is remarkably deteriorated, so the lifetime is short. However, because the cover window according to the present exemplary Embodiment includes the rubber particles with the core/shell structure, the photo reactive portions (e.g., photoreactors) reacting with the natural light are not dispersed inside the matrix, and accordingly the lifetime is longer.

As described above, when the cover window according to the present disclosure includes the rubber particles with the core/shell structure inside the polymer resin layer 310 and the thickness of the film 320 is formed at 100 μm to 200 μm, both the impact resistance and the hardness of the cover window are good (e.g., excellent), the weathering resistance is good (e.g., excellent), and the lifetime is long. This cover window may be utilized as a cover window for various display devices. For example, with high impact resistance and hardness, the cover window is suitable to be utilized as a cover window of a mobile apparatus.

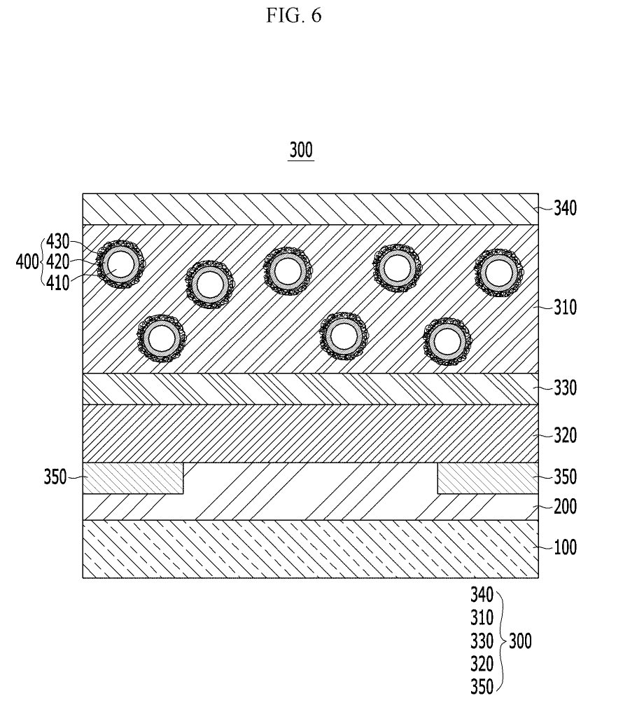

Next, the display device to which the cover window according to an exemplary embodiment is applied will be described. FIG. 6 is a cross-sectional view showing a display device according to an exemplary embodiment. Referring to FIG. 6, the display device according to an exemplary embodiment includes a display panel 100, a cover window 300, and a panel adhesive layer 200 bonding the display panel 100 and the cover window 300. The description of the cover window 300 is substantially the same as described above and the detailed description thereof is not repeated.

The panel adhesive layer 200 may adhere the display panel 100 and the cover window 300 together, and may include the OCA, the SVR, the PSA, the OCR, or combinations thereof. For example, the panel adhesive layer 200 may the transparent adhesive layer including the OCA or the OCR.

The display panel 100 may be a liquid crystal panel or an organic light emitting panel. When the display panel 100 is the liquid crystal panel, a first substrate and a second substrate facing each other, and a liquid crystal layer positioned therebetween may be included. When the display panel 100 is the organic light emitting panel, a first substrate and an organic light emitting element positioned on the first substrate may be included.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims, and equivalent thereof.

Description of symbols

| | |
|---|---|
| 100: display panel | 200: panel adhesive layer |
| 300: cover window | 310: polymer resin layer |
| 315: matrix | 320: film |
| 330: adhesive layer | 340: hard coating layer |
| 350: light blocking layer | 400: particle |
| 410: core | 420: shell |
| 430: outermost portion | |

What is claimed is:

1. A cover window comprising:
a polymer resin layer; and
a film on one surface of the polymer resin layer,
wherein the polymer resin layer comprises a matrix and particles having a core/shell structure dispersed in the matrix,
a core of the particles having the core/shell structure comprises polymethyl methacrylate, and a shell of the particles having the core/shell structure comprises a copolymer of butyl acrylate and styrene.

2. The cover window of claim 1, wherein
the matrix comprises polymethyl methacrylate.

3. The cover window of claim 1, further comprising
polymethyl methacrylate grafted to an outermost portion of the particles.

4. The cover window of claim 1, wherein
a content of the particles is in a range of 10 wt % to 20 wt % based on a total weight of the polymer resin layer.

5. The cover window of claim 1, wherein
a thickness of the polymer resin layer is in a range of 600 μm to 1000 μm.

6. The cover window of claim 1, wherein
the film comprises at least one material selected from the group consisting of polyethylene terephthalate (PET), polyethylene naphthalate (PEN), a cycloolefin polymer (COP), and polycarbonate (PC).

7. The cover window of claim 1, wherein
a thickness of the film is in a range of 100 μm to 200 μm.

8. The cover window of claim 1, further comprising
an adhesive layer between the film and the polymer resin layer.

9. The cover window of claim 8, wherein
the adhesive layer comprises an optically clear adhesive, and has an adherence of 30 N/inch or greater.

10. The cover window of claim 1, wherein
an entire thickness of the cover window is 1200 μm or less.

11. The cover window of claim 1, wherein
a pencil hardness of the cover window is 4H or greater.

12. The cover window of claim 1, wherein
a content of the particles is a range of 10 wt % to 16 wt % based on a total weight of the polymer resin layer.

13. The cover window of claim 12, wherein
a pencil hardness of the cover window is 7H or greater.

14. The cover window of claim 1, further comprising
a hard coating layer on an other surface of the polymer resin layer facing away from the one surface.

15. The cover window of claim 1, further comprising
a light blocking layer on one surface of the film.

16. A display device comprising:
a display panel; and
a cover window on one surface of the display panel,
wherein the cover window comprises:
a polymer resin layer, and
a film on one surface of the polymer resin layer,
wherein the polymer resin layer comprises a matrix and particles having a core/shell structure dispersed in the matrix, and
a core of the particles having the core/shell structure comprises polymethyl methacrylate, and a shell of the particles having the core/shell structure comprises a copolymer of butyl acrylate and styrene.

17. The display device of claim 16, wherein
the matrix comprises polymethyl methacrylate.

18. The display device of claim 16, further comprising
polymethyl methacrylate grafted to an outermost portion of the particles.

19. The display device of claim 16, wherein
a content of the particles is in a range of 10 wt % to 20 wt % based on a total weight of the polymer resin layer.

20. The display device of claim 16, further comprising:
a hard coating layer on the polymer resin layer; and
a light blocking layer between the film and the display panel.
